(19) United States
(12) Patent Application Publication
(10) Pub. No.: US 2026/0239934 A1
(43) Pub. Date: Aug. 13, 2026

(54) SQUARE SILICON SUBSTRATE AND MANUFACTURING METHOD THEREFOR

(71) Applicant: MITSUBISHI MATERIALS CORPORATION, Tokyo (JP)

(72) Inventors: Daisuke Kaneko, Sanda-shi (JP); Shinji Kato, Sanda-shi (JP)

(73) Assignee: MITSUBISHI MATERIALS CORPORATION, Tokyo (JP)

(21) Appl. No.: 19/151,468

(22) PCT Filed: Mar. 26, 2024
(86) PCT No.: PCT/JP2024/011854

§ 371 Date: Jul. 28, 2025

(30) Foreign Application Priority Data
Apr. 5, 2023 (JP) 2023-061295

(51) Int. Cl. H10P 90/00; B28D 5/02

(52) U.S. Cl. CPC H10P 90/129; B28D 5/02; H10P 90/123

(57) ABSTRACT

There is provided a method for manufacturing a square silicon substrate having a first surface for circuit formation and a second surface located opposite to the first surface. The method includes: a slicing step of slicing a silicon ingot to form a square plate member; a grinding step of grinding both surfaces of the plate member; a polishing step of mechanically polishing one surface of the plate member subjected to the grinding step to form a square silicon substrate having the first surface, in which the square silicon substrate is formed to have a thickness of 0.5 mm or more and 2.0 mm or less without performing chemical etching in the grinding step, in the polishing step, and between the polishing step and the grinding step.

### TECHNICAL FIELD

The present invention relates to a silicon substrate for a semiconductor.

Priority is claimed on Japanese Patent Application No. 2023-061295, filed Apr. 5, 2023, the content of which is incorporated herein by reference.

### BACKGROUND ART

A silicon substrate formed by slicing a silicon ingot is used as a substrate for a semiconductor in the related art.

The silicon substrate for manufacturing a plurality of semiconductor chips consists of single-crystal silicon and has a circular outer shape. In addition, the silicon substrate for a solar panel mainly consists of polycrystalline silicon, and has a rectangular outer shape.

### CITATION LIST

### Patent Documents

Patent Document 1: Japanese Patent No. 5401683
Patent Document 2: Japanese Unexamined Patent Application, First Publication No. 2017-208571
Patent Document 3: Japanese Unexamined Patent Application, First Publication No. 2015-6990
Patent Document 4: Japanese Unexamined Patent Application, First Publication No. 2006-202831

### Non Patent Document

Non Patent Document 1: Published in July 2002, JEITA EM-3602 “Standard Specification for Dimensional Standards of Silicon Mirror Wafer”, Japan Electronics and Information Technology Industries Association

### SUMMARY OF INVENTION

### Technical Problem

Meanwhile, a method for manufacturing a silicon substrate consisting of single-crystal silicon for manufacturing a semiconductor chip is disclosed in Patent Document 1. However, as shown in Non Patent Document 1, a silicon substrate for a semiconductor chip is formed in a circular shape by using a silicon ingot, and an inner region excluding a peripheral edge portion is utilized for circuit formation, and there is a region that is not utilized. It is desirable that the silicon substrate is utilized including a peripheral edge portion thereof.

In manufacturing of a large square silicon substrate, in a case where a surface is polished, only corner portions are scraped, and a thickness variation may occur in a plane.

In addition, as a method for manufacturing a silicon substrate, chemical etching is performed on a plate member formed by slicing a silicon ingot (Patent Documents 2, 3, and 4), but in a case where chemical etching using an acid solution is performed on a round or square plate member consisting of polycrystalline silicon, grain boundaries may be preferentially scraped or only the grain boundaries may not be scraped, and there is a concern that the surface subjected to etching may be rough. In addition, in the chemical etching, a scraping rate varies depending on a crystal plane orientation of the plate member, and thus there is a concern that the surface may be rough.

Therefore, an object of the present invention is to provide a square silicon substrate and a manufacturing method therefor.

### Solution to Problem

The square silicon substrate according to the embodiment of the present invention has a thickness of 0.5 mm or more and 2.0 mm or less, a total thickness variation (hereinafter, referred to as TTV) in a first surface for circuit formation is 100.0 μm or less, and a maximum peak height Rp of the first surface is 100.0 nm or less.

The term “square” means that in a case where the square silicon substrate is viewed in plan view, four corner portions are disposed on a peripheral edge, and a contour forms a rectangle. It is noted that the square shape includes a shape in which one or more of the four corner portions are cut out and formed as cutout portions. In the square silicon substrate, since a variation in overall thickness including the peripheral edge portion is small and roughness of the first surface for circuit formation is also small and has high flatness, the entire region of the first surface can be used for circuit formation. In addition, the dimensions of the square silicon substrate are not limited, but the square silicon substrate is formed in a square shape having a length of a side of 300 mm or more, for example. In a case where the thickness of the square silicon substrate is less than 0.5 mm, warping occurs, and in a case where the thickness of the square silicon substrate is more than 2.0 mm, a weight increases, and it is difficult to transport the square silicon substrate.

In a case where the TTV is more than 100.0 μm, it is difficult to form a fine wiring pattern in which a line width on the first surface is 2 μm. The formation of the fine wiring pattern is also difficult in a case where the maximum peak height Rp of the first surface is more than 100.0 nm.

The square silicon substrate according to the embodiment of the present invention consists of polycrystalline silicon and preferably consists of columnar crystal silicon.

Since the thickness variation and roughness are reduced in the silicon substrate, there is an advantage that the silicon substrate can be used for a semiconductor chip even in a case of consisting of polycrystalline silicon, and in a case of consisting of columnar crystal silicon, the bending strength is increased and cracking can be further prevented as compared with a case of consisting of single-crystal silicon or polycrystalline silicon (excluding columnar crystal silicon).

In the square silicon substrate according to the embodiment of the present invention, a value (TTV/S1) obtained by dividing TTV by an area (S1 [mm²]) of the first surface is preferably 1.00×10⁻6 [mm⁻¹] or less.

This value (TTV/S1) is considered as a flatness with respect to the area of the square silicon substrate, and in a case where the value (TTV/S1) is 1.00×10⁻⁶ [mm⁻¹] or less, a deviation in a thickness direction in an exposure step for forming a wiring is small, and formation of a fine wiring is possible. However, in a case where the thickness is more than 1.00×10⁻⁶ [mm⁻¹], the deviation in the thickness direction in the exposure step for forming a wiring increases, and it is difficult to form a fine wiring, which is not preferable.

In the square silicon substrate according to the embodiment of the present invention, arithmetic average roughness Ra of the first surface is preferably 2.0 nm or less.

By setting the arithmetic average roughness Ra to 2.0 nm or less, a fine wiring pattern can be formed. In a case where the arithmetic average roughness Ra is more than 2.0 nm, it is difficult to form a fine wiring pattern.

A method for manufacturing a square silicon substrate according to an embodiment of the present invention is a method for manufacturing a square silicon substrate having a first surface for circuit formation and a second surface located opposite to the first surface, the method including: a slicing step of slicing a silicon ingot to form a square plate member; a grinding step of grinding both surfaces of the plate member; and a polishing step of mechanically polishing one surface of the plate member subjected to the grinding step to form the first surface in the square silicon substrate, in which the square silicon substrate is formed to have a thickness of 0.5 mm or more and 2.0 mm or less without performing chemical etching in the grinding step, in the polishing step, and between the grinding step and the polishing step.

The term “mechanical polishing” is polishing by scraping a surface to be polished with abrasive grains or the like to remove unevenness or the like without a chemical action of dissolving or altering the surface to be polished, and the term “mechanical polishing” excludes “mechanochemical polishing” which is mechanical polishing accompanied by chemical polishing.

In the method for manufacturing the silicon substrate according to the embodiment of the present invention, the first surface is formed with a small thickness variation by mechanically polishing one surface of the plate member subjected to the grinding step without performing chemical etching with an acid solution, and the entire region of the first surface is formed to be flat with small roughness.

In the method for manufacturing the silicon substrate according to the embodiment of the present invention, preferably, in the polishing step, slurry for finishing consisting of abrasive grains for finishing and a liquid having a hydrogen ion exponent [pH] of 7.0 or more and 9.0 or less is used. In the polishing step, the abrasive grains for finishing that do not cause a chemical action are used, and therefore, pure water is preferably used as a liquid.

By performing the mechanical polishing without performing the chemical etching with an acid solution, a situation in which an etching amount varies at each position on the plate member does not occur, and the entire first surface can be subjected to a polishing process in a substantially uniform manner.

### Advantageous Effects of Invention

According to the present invention, it is possible to manufacture a large square substrate in which a thickness variation is small as a whole and flatness of a circuit forming surface is good. The use thereof is not limited, but in a case of being used for manufacturing a semiconductor chip, the number of chips that can be taken out can be increased, and the manufacturing cost and the unit price of the chip can be reduced.

### BRIEF DESCRIPTION OF DRAWINGS

FIG. 1A Aplan view of a square silicon substrate according to an embodiment of the present invention.

FIG. 1B A partially enlarged view of a cross-section of the square silicon substrate taken along line S1-S1 in FIG. 1A.

FIG. 2 A plan view representing a modification example of the square silicon substrate according to the embodiment of the present invention.

FIG. 3 A flowchart representing a step of manufacturing the square silicon substrate according to the embodiment of the present invention.

### DESCRIPTION OF EMBODIMENTS

Hereinafter, a square silicon substrate 1 according to an embodiment of the present invention will be described with reference to the drawings.

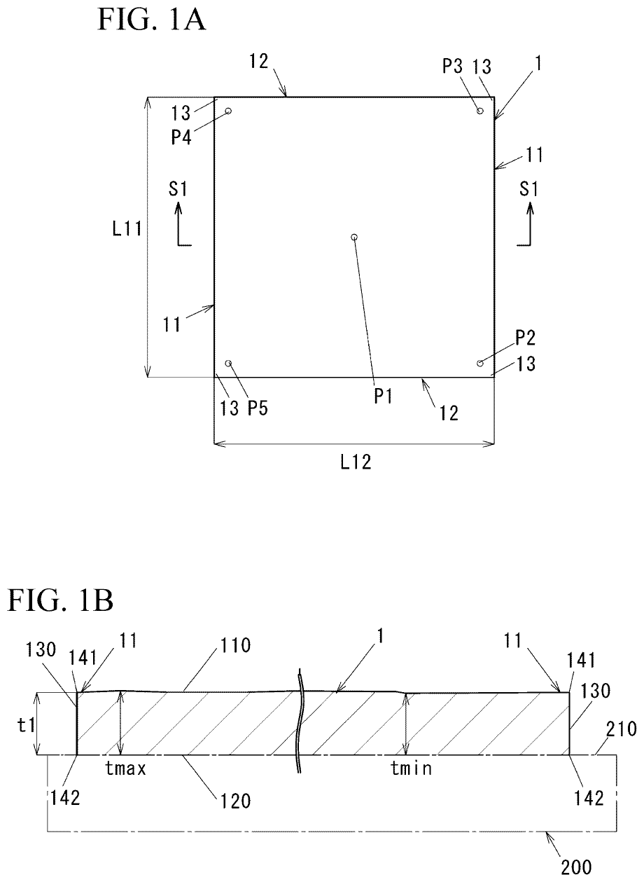

As shown in FIG. 1A, in a case where square silicon substrate 1 is viewed in plan view, a pair of first edge portions 11 extending linearly in parallel and a pair of second edge portions 12 disposed at right angles to the first edge portions 11 and extending linearly in parallel are connected to each other, and a peripheral edge is formed in a rectangular shape. Lengths L11 and L12 of the first edge portions 11 and the second edge portions 12 are not limited, but are, for example, 300 mm or more and 900 mm or less. It is noted that the lengths L11 and L12 of the first edge portions 11 and the second edge portions 12 are not particularly limited, but may be 400 mm or more and 900 mm or less, or may be 500 mm or more and 900 mm or less. In addition, in the square silicon substrate 1, each of four positions where the first edge portions 11 and the second edge portions 12 are connected to each other is referred to as a corner portion 13.

As shown in FIG. 1B, the square silicon substrate 1 has a first surface 110 for circuit formation and a second surface 120 located opposite to the first surface 110. Furthermore, the square silicon substrate 1 consists of single-crystal or polycrystalline silicon, and preferably, in polycrystalline silicon, columnar crystal silicon obtained by carrying out crystal growth in one direction is used. In a case where the square silicon substrate 1 consists of columnar crystal silicon, the first surface 110 and the second surface 120 of the square silicon substrate 1 are formed to intersect a crystal growth direction.

In the first edge portions 11 and the second edge portions 12 constituting the peripheral edge portion of the square silicon substrate 1, as shown in FIG. 1B, a first edge 141 is formed by the first surface 110 and an outer peripheral end surface 130, and a second edge 142 is formed by the second surface 120 and an outer peripheral end surface 130.

The thickness t1 of the square silicon substrate 1 is, for example, 0.5 mm or more and 2.0 mm or less. The thickness t1 is specified by measuring the thicknesses of the central measurement point P1 and the four corner portion measurement points P2 to P5 by using a micrometer or a three-dimensional measuring machine, and obtaining an average value thereof. It is noted that in FIG. 1, five measurement points are represented by circles. The central measurement point P1 is a position where one virtual line connecting corner portions disposed diagonally with each other in the contour in plan view and the other virtual line intersect each other. Each of the corner portion measurement points P2 to P5 is a position that is located 10 mm inward from the first edge portions 11 and the second edge portions 12 at the periphery of each corner portion.

In the square silicon substrate 1, the entire region of the first surface 110 including the peripheral edge portion of the square silicon substrate 1 has small roughness and high flatness. Specifically, the first surface 110 has arithmetic average roughness Ra of, for example, 2.1 nm or less, and preferably 2.0 nm or less. Although not particularly limited, the arithmetic average roughness Ra may be 0.001 nm or more. In addition, the first surface 110 has a maximum peak height Rp of, for example, 100.0 nm or less, and preferably 50.0 nm or less. Although not particularly limited, the maximum peak height Rp may be 0.01 nm or more.

It is noted that the square silicon substrate 1 is formed by reducing the thickness variation, and the total thickness variation (TTV) thereof is, for example, 100.0 μm or less, preferably 70.0 μm or less, and more preferably 40.0 μm or less. Although not particularly limited, TTV may be 0.1 m or more.

Here, TTV is a difference (tmax−tmin) between the maximum thickness tmax of the square silicon substrate 1 and the minimum thickness tmin of the square silicon substrate 1. The second surface 120 of the square silicon substrate 1 is fixed to a placement surface of a surface plate for measurement with a suction device or the like, the maximum thickness (dimension) of the square silicon substrate 1 from a reference surface is obtained as the maximum thickness tmax with the placement surface set as a reference surface, and the minimum thickness (dimension) of the square silicon substrate 1 from the reference surface is obtained as the minimum thickness tmin. Both the maximum thickness tmax and the minimum thickness tmin are targeted for the entire region of the first surface 110 including the peripheral edge portion of the square silicon substrate 1. It is noted that in FIG. 1B, the surface plate 200 for measurement is represented by a one-dot chain line, and a state in which the second surface 120 of the square silicon substrate 1 is fixed to a placement surface 210 of the surface plate 200 for measurement is shown.

Furthermore, in the square silicon substrate 1, a value (unit: mm⁻¹: TTV/S1) obtained by dividing TTV by the area S1 (mm²) of the first surface 110 is considered as the flatness with respect to the area of the square silicon substrate 1, and is, for example, 1.00×10⁻⁶ mm⁻¹ or less, preferably 0.50×10⁻⁶ mm¹ or less, and more preferably 0.20×10⁻⁶ mm⁻¹ or less. Although not particularly limited, TTV/S1 may be 0.10×10⁻⁶ mm⁻¹ or more.

The square silicon substrate 1 may include a position specifying unit formed on a part of the peripheral edge as a reference for specifying two-dimensional position information in a plane, for example, as a mark serving as the origin.

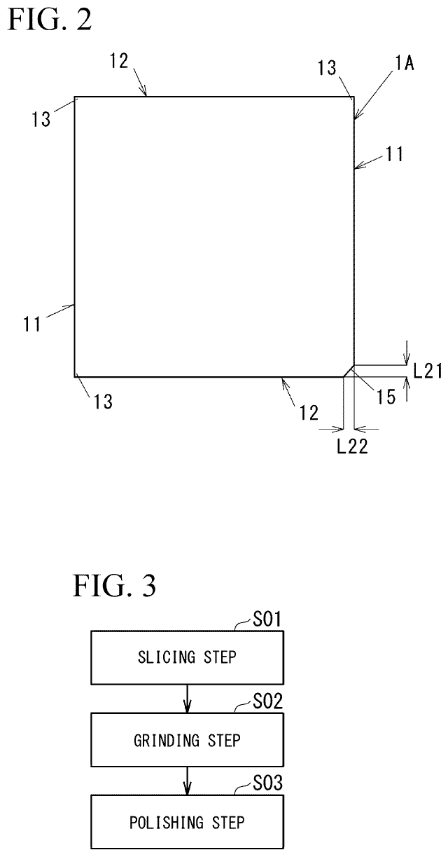

For example, in a square silicon substrate 1A shown in FIG. 2, one corner portion 13 is cut out to be formed as a cutout portion 15 such that a shape of one corner portion is different from shapes of the other three corner portions. In the cutout portion 15, for example, a dimension L21 along a first direction in which the first edge portion 11 extends is 1.0 mm or more and 20.0 mm or less, a dimension L22 along a second direction (orthogonal to the first direction) in which the second edge portion 12 extends is 1.0 nmm or more and 20.0 mm or less, and the cutout portion 15 is sufficiently short with respect to the first edge portion 11 or the second edge portion 12 of the square silicon substrate 1A. In this case, the square silicon substrate 1A also has an outer shape that is substantially rectangular when viewed from the first surface 110 side. The cutout portion 15 is not limited to a form that extends linearly in plan view when viewed from the first surface 110 side, and may be formed in an arc shape or the like. It is noted that the cutout portion 15 may be formed as a so-called notch in which a part of the edge extending in a straight line is cut out. The position specifying unit can also be utilized for identifying directionality of the square silicon substrate 1A. As described above, the square silicon substrate 1 in which the corner portions are intentionally cut out is also within the scope of the technical idea of the present invention.

### (Method for Manufacturing Square Silicon Substrate 1)

As shown in FIG. 3, a method for manufacturing the square silicon substrate 1 includes a slicing step S01 of slicing a silicon ingot to form a plate member, a grinding step S02 of grinding both surfaces of the plate member, and a polishing step S03 of subjecting one surface of the plate member to a polishing process after the grinding step S02. Hereinafter, one surface of the plate member will be referred to as a first machined surface, and the other surface located opposite to the first machined surface will be referred to as a second machined surface.

### (Slicing Step S01)

In the slicing step S01, a plate member having a thickness of, for example, 1.0 mm or more and 2.2 mm or less is cut from a single-crystal or polycrystalline silicon ingot by using a band saw or a wire saw to which diamond abrasive grains are fixed. A silicon ingot having a prismatic or cylindrical shape can be used.

As the prismatic silicon ingot, for example, a silicon ingot having a length of 300 mm or more and 1200 mm or less, a width of 300 mm or more and 1200 mm or less, and a height (thickness) of 10 mm or more and 300 mm or less can be used. The plate member is formed in a square or rectangular shape as an outer shape in plan view when viewed from the first machined surface side.

A silicon ingot of columnar crystal is formed by injecting a molten silicon into a mold in which a horizontal cross-section is formed in a rectangular or circular shape, cooling the mold from below to solidify the silicon in the mold in one direction from below to above and to form a prismatic or cylindrical silicon ingot obtained, and grinding and polishing a surface thereof, and a columnar crystal silicon ingot formed in a desired rectangular parallelepiped shape is used.

In addition, in a case where a silicon ingot of a columnar crystal is used, the silicon ingot is sliced such that the first machined surface of the plate member and the second machined surface of the plate member located opposite to the first machined surface intersect a crystal growth direction.

As the cylindrical silicon ingot, for example, a silicon ingot having a diameter of 400 mm or more and 1200 mm or less and a height (thickness) of 10 mm or more and 300 mm or less can be used. In a case where the cylindrical silicon ingot is used, the plate member is formed in a circular shape in plan view when viewed from the first machined surface side.

It is noted that for example, a silicon ingot having a diameter cp of 450 mm or more and consisting of polycrystals is used. For a cylindrical shape, a polycrystal is used in a case where dimensions in the vertical and horizontal directions are large.

### (Grinding Step S02)

In the grinding step S02, the first machined surface and the second machined surface are scraped to perform rough polishing of the first machined surface and the second machined surface. It is noted that since chamfering of the peripheral edge portion of the plate member is not performed between the slicing step S01 and the grinding step S02, both the first machined surface and the second machined surface are cross-sections formed in the slicing step S01. In the grinding step S02, polishing rougher than the polishing in the polishing step is performed, for example, by a lapping machine as a pretreatment of the polishing step. Hereinafter, the lapping process performed on the first machined surface and the second machined surface by the lapping machine will be referred to as a lapping step.

In the lapping machine, a plate member is held by a carrier, and slurry for lapping is put between a rotating lapping surface plate and a surface to be polished to perform polishing.

The slurry for lapping consists of abrasive grains for lapping and a liquid for lapping, and a hydrogen ion exponent (pH) of the slurry for lapping is 7.0 or more and 9.0 or less. The abrasive grains for lapping consist of SiC or Al₂O₃. As the liquid for lapping, for example, pure water, an anionic surfactant such as sodium laurate, a cationic surfactant such as dodecylamine hydrochloride, a nonionic surfactant such as polyethylene glycol mono-4-nonylphenyl ether, or a polyhydric alcohol such as glycol can be used.

In the lapping machine, the first machined surface side and the second machined surface side of the plate member protruding from the carrier are polished so that the thickness of the plate member after the lapping step is close to the carrier thickness. In the lapping step, the thickness of the plate member protruding from the carrier is preferably 0.1 mm or more and 0.5 mm or less, and thus the entire first machined surface or the entire second machined surface can be suitably polished. It is noted that in a case where the thickness of the plate member protruding from the carrier is more than 0.5 mm, there is a risk that the edge of the first machined surface or the second machined surface may be damaged, and in a case where the thickness of the plate member protruding from the carrier is less than 0.1 mm, the carrier may be scraped and deformed, and thus the plate member may be detached.

Arithmetic average roughness Ra of the first machined surface and the second machined surface of the plate member after the lapping step is, for example, 1.0 μm or less.

The thickness of the plate member after the lapping step is, for example, 1.0 mm or more and 2.2 mm or less.

In addition, in the grinding step S02 of reducing the roughness of the first surface and the second surface of the plate member before performing the polishing step, plane grinding of the plate member may be performed by using a plane grinding machine instead of the lapping step. In the plane grinding machine, unevenness or the like of the first machined surface and the second machined surface of the plate member may be removed by a grinding wheel provided in the rotating grinding machine. The grinding wheel is fixed to the grinding machine, and this grinding wheel also consists of SiC or Al₂O₃. The arithmetic average roughness Ra is set to, for example, 1.0 μm or less even on the first machined surface and the second machined surface of the plate member after the grinding step S02.

### (Polishing Step S03)

In the polishing step S03, finishing of the first machined surface that has been subjected to the grinding step S02 is performed mechanically by a polishing device. It is noted that since the chemical etching for removing unevenness or the like is not performed on the first machined surface of the plate member between the grinding step S02 and the polishing step S03, the first machined surface subjected to the surface treatment in the polishing step S03 is a lapping machined surface.

In the polishing device, the plate member is held by a carrier, and slurry for finishing is put between a rotating pad and a surface to be polished, and polishing is performed.

The slurry for finishing consists of abrasive grains for finishing and a liquid for finishing, and a hydrogen ion exponent (pH) of the slurry for finishing is 7.0 or more and 9.0 or less. The abrasive grains for finishing consist of SiO₂, and as the liquid for finishing, for example, pure water, an anionic surfactant such as sodium laurate, a cationic surfactant such as dodecylamine hydrochloride, a nonionic surfactant such as polyethylene glycol mono-4-nonylphenyl ether, or a polyhydric alcohol such as glycol can be used, and the pure water is preferably used.

In the polishing device, the first machined surface side of the plate member protruding from the carrier is polished so that the thickness of the plate member after the polishing step S03 is close to the carrier thickness. In the polishing step S03, the thickness of the plate member protruding from the carrier is preferably 0.1 mm or more and 0.5 mm or less, and thus the entire first machined surface can be suitably polished. It is noted that in a case where the thickness of the plate member protruding from the carrier is more than 0.5 mm, there is a risk that the edge of the first machined surface may be damaged, and in a case where the thickness of the plate member protruding from the carrier is less than 0.1 mm, the carrier may be scraped and deformed, and thus the plate member may be detached.

After the polishing step S03, the arithmetic average roughness Ra of the first machined surface is set to, for example, 2.0 nm or less, the maximum peak height Rp of the first machined surface is set to, for example, 100.0 nm or less, the thickness t1 is set to, for example, 0.5 mm or more and 2.0 mm or less, the TTV is set to, for example, 100.0 μm or less, and the value (TTV/S1) obtained by dividing the TTV by the area S1 of the first machined surface is set to, for example, 1.00×10⁻⁶ mm⁻¹ or less. Through such a polishing step S03, the first machined surface is formed as the first surface 110 that is a mirror surface, and the silicon substrate is completed.

In the silicon substrate of the present embodiment, since the unevenness or the like on the surface of the plate member is removed without performing chemical etching in the grinding step S02, in the polishing step S03, and between the grinding step S02 and the polishing step S03, the variation in the overall thickness including the peripheral edge portion is small, and the roughness of the first surface 110 for circuit formation is also small and has high flatness, the entire region of the first surface 110 including the peripheral edge portion can be used for circuit formation. Therefore, in the silicon substrate of the present embodiment, a process of forming a wiring pattern or the like can be performed on the entire region including the peripheral edge portion.

The silicon substrate of the present embodiment can increase the number of semiconductor chips and the like that can be obtained as compared with a round silicon substrate on which a process of forming a wiring pattern in a region on an inner side of a peripheral edge portion is performed without utilizing the peripheral edge portion, and thus can reduce the manufacturing cost and the unit price of the product.

In a case where the thickness of the square silicon substrate is less than 0.5 mm, warping occurs, and in a case where the thickness of the square silicon substrate is more than 2.0 mm, a weight increases, and it is difficult to transport the square silicon substrate.

In a case where TTV is more than 100.0 am, it is difficult to form a fine wiring pattern in which the line width on the first surface is 2 μm. Even in a case where the maximum peak height Rp of the first surface 110 is more than 100.0 nm, it is difficult to form a fine wiring pattern.

In particular, in the polycrystalline silicon substrate subjected to chemical etching in the related art, the grain boundary is preferentially scraped, or the grain boundary remains, and the TTV or the maximum peak height Rp may be increased. However, even in a case where the square silicon substrate 1 consists of polycrystalline silicon, the first surface 110 is formed such that the TTV or the maximum peak height Rp is small, and thus, the circuit formation can be satisfactorily performed.

In a case where the silicon substrate consists of columnar crystal silicon, the bending strength of the substrate is increased as compared with a case where the silicon substrate consists of a single-crystal or a polycrystal other than a columnar crystal, and thus cracking can be prevented.

Further, in a case where the value (TTV/S1) is 1.00×10⁻⁶ [mm⁻¹] or less, a deviation in the thickness direction in an exposure step for forming the wiring is small, and the formation of the fine wiring is possible. In a case where the value (TTV/S1) is more than 1.00×10⁻⁶ [mm⁻¹], the deviation in the thickness direction in the exposure step for forming a wiring increases, and it is difficult to form a fine wiring, which is not preferable.

By setting the arithmetic average roughness Ra to 2.0 nm or less, a fine wiring pattern can be formed. In a case where the arithmetic average roughness Ra is more than 2.0 nm, it is difficult to form a fine wiring pattern.

In particular, in the polycrystalline silicon substrate subjected to chemical etching in the related art, the grain boundary is preferentially scraped, or the grain boundary remains, and the arithmetic average roughness Ra may be increased. However, even in a case where the square silicon substrate 1 consists of polycrystalline silicon, the first surface 110 is formed such that the arithmetic average roughness Ra is small, and thus, circuit formation can be satisfactorily performed.

In the related art, in a case where a plate member is chemically etched, there may be a difference in etching amount due to an acid solution at each position of the plate member, but in the method for manufacturing the square silicon substrate according to the present embodiment, the entire surface can be subjected to a polishing process substantially uniformly.

The present invention can be carried out without limitation to the above description and the illustrated examples.

Although a case where the length of the side is 300 mm or more is an exemplary example as the size of the silicon substrate, the present invention can also be applied to a case where a silicon substrate having a length of the side of less than 300 mm is manufactured.

In addition, the use of the square silicon substrate is not limited, but for example, in a case of being used as a substrate such as an interposer, the square silicon substrate itself is formed to be thin, so that it is possible to reduce the thickness of the entire packaged chip. In addition, the silicon substrate of the present embodiment can also be utilized as a substrate for a solar panel.

### (Directionality Identification)

In a case where the square silicon substrate has a portion chamfered at a part of the peripheral edge, the directionality of the square silicon substrate can be identified. In addition, as a configuration example for performing the other directionality identification, a configuration in which all of peripheral edges of the square silicon substrate are chamfered and a portion where a part of the peripheral edges protrudes is provided in plan view is adopted.

### EXAMPLES

A plurality of silicon substrates having different outer shapes and thicknesses were manufactured, and the outer shapes, the thicknesses, a thickness variation, and roughness of the first surface were evaluated.

The method for manufacturing the silicon substrate includes a slicing step of slicing a silicon ingot to form a plate member, a grinding step of grinding both surfaces (a first machined surface and a second machined surface) of the sliced plate member, and a polishing step of subjecting the first machined surface of the plate member to a polishing process after the grinding step. It is noted that in the method for manufacturing the silicon substrate, a beveling step of chamfering the peripheral edge of the sliced plate member between the slicing step and the grinding step is not performed, and an etching step of performing chemical etching on both surfaces (the first machined surface and the second machined surface) of the plate member between the grinding step and the polishing step is also not performed.

### (Grinding Step)

The grinding step was performed by using either a lapping machine or a plane grinding machine.

In the lapping machine, the plate member was held by a carrier, and slurry for lapping was put between a rotating lapping surface plate and a surface to be polished to perform polishing.

The slurry for lapping consists of abrasive grains for lapping and a liquid for lapping.

The abrasive grains for lapping consist of SiC or Al₂O₃. The liquid for lapping consists of pure water, and an anionic surfactant such as sodium laurate, a cationic surfactant such as dodecylamine hydrochloride, a nonionic surfactant such as polyethylene glycol mono-4-nonylphenyl ether, and polyhydric alcohol such as glycol may be added. A grinding wheel is fixed to the grinding machine, and the grinding wheel consists of the same material as the abrasive grains for lapping. In the plane grinding machine, unevenness and the like of the first machined surface and the second machined surface of the plate member are removed by the grinding wheel provided in the rotating grinding machine. The grinding wheel provided in the grinding machine consists of SiC or Al₂O₃.

### (Polishing Step)

In the polishing step, the first machined surface of the plate member subjected to the grinding step was subjected to mechanical polishing with a polishing device to finish the surface to a mirror surface.

In the polishing device, slurry for finishing was put between a rotating pad and a surface to be polished in a state in which the plate member was held by a carrier, and the first machined surface was polished.

The slurry for finishing consists of abrasive grains for finishing and a liquid for finishing. The abrasive grains for finishing consist of SiO₂, the slurry for finishing consists of pure water, and an anionic surfactant such as sodium laurate, a cationic surfactant such as dodecylamine hydrochloride, a nonionic surfactant such as polyethylene glycol mono-4-nonylphenyl ether, and polyhydric alcohol such as glycol may be added.

Among specimens manufactured by the method for manufacturing a silicon substrate, Specimens 1 to 21 are specimens using a prismatic silicon ingot. Among these, Specimen 17 consists of single-crystal silicon, Specimen 12 consists of polycrystalline silicon (excluding columnar crystals), and the other specimens consist of columnar crystal silicon. It is noted that in the silicon substrate consisting of the columnar crystal silicon, a first surface and a second surface are formed to intersect a growth direction of the columnar crystal. Specimens 1 to 21 have a square or rectangular outer shape when viewed in plan view from the first surface side.

A cylindrical silicon ingot is used as Specimen 22, and the outer shape thereof is circular in plan view from the first surface side.

Among the above-described manufacturing methods, a square silicon substrate manufactured by the slicing step and the grinding step without the polishing step is Specimen 23.

In addition, a square silicon substrate manufactured, as the manufacturing method, through the slicing step, the grinding step, the etching step of performing chemical etching on the first machined surface after the grinding step, and the polishing step of performing polishing on the etched surface after the etching step is Specimen 24. In addition, a glass substrate was used as Specimen 25 as a reference example.

For each specimen, Table 1 shows a material and a crystal type constituting the ingot, dimensions (horizontal, vertical) [mm] of the outer shape of the plate member obtained by slicing the ingot, the number of corner portions disposed on a contour line in a case where the plate member is viewed in plan view from the first machined surface side, and a thickness t2 [mm] of the plate member.

It is noted that the dimensions (horizontal, vertical) of the outer shape of the plate member after slicing were measured using a three-dimensional measuring machine (Quick Vision manufactured by Mitutoyo Corporation). The first decimal place of the dimensions (horizontal, vertical) [mm] of the outer shape was rounded off to obtain a value (integer) as significant figures.

The thickness t2 of the plate member after the slicing step, the thickness t3 of the plate member after the grinding step, and the thickness t4 of the plate member after the polishing step, which will be described later, were measured by using a flatness measuring device of an optical interferometer method. It is noted that in order to specify the thickness of the plate member, the thickness of the central measurement point of the plate member and the thickness of each of the four corner portion measurement points of the plate member were measured after each step, and average values thereof were defined as the thicknesses t2, t3, and t4. The central measurement point P1 is a position where one virtual line connecting corner portions disposed diagonally with each other in the contour in a case where the plate member is viewed in plan view and the other virtual line intersect each other. The corner portion measurement point is a position that is 10 mm inward from each of the first edge portion and the second edge portion constituting the corner portion at the periphery of each corner portion. For t2, t3, and t4 [mm], the value obtained by rounding off the second decimal place is set as the significant figures. In the plate member formed in a circular shape that is Specimen 19, the thicknesses at four positions of the center and a circular edge were measured at intervals of 10 mm, and t2, t3, and t4 were obtained as average values thereof.

For each specimen, Table 2 shows the type of device (lapping machine and plane grinding machine) for performing the grinding step, the material constituting the abrasive grains and the grinding wheel in the grinding step, the thickness t3 [mm] of the silicon substrate after the grinding step and before the polishing step, the presence or absence of the etching step, the presence or absence of the polishing step, the hydrogen ion exponent (pH) of the slurry for finishing in the polishing step, and the thickness t4 [mm] of the silicon substrate after the polishing step. The hydrogen ion exponent [pH] has a value obtained by rounding off a second decimal place as a significant figure.

In addition, Table 3 shows the TTV of each specimen manufactured through the polishing step, the maximum peak height Rp of the first surface (mirror surface), a value (TTV/S1) obtained by dividing the TTV by the area S1 of the first surface, and the arithmetic average roughness Ra of the first surface.

Since the contour shape and the dimensions of the plate member subjected to the polishing step in plan view when viewed from the first surface side are the same as the outer shape and the dimensions of the plate member after table slice fixation, the area S1 was obtained by multiplying a vertical dimension and a horizontal dimension in Table 1. The value (TTV/S1) [mm⁻¹] has a significant figure of a value obtained by rounding off a ninth decimal place.

It is noted that the region for circuit formation, which is a measurement target for the TTV, the maximum peak height Rp, the arithmetic average roughness Ra, and the thickness t4, is the entire first surface. In addition, the TTV of the silicon substrate after the polishing step was calculated as a difference (tmax−tmin) by measuring a maximum thickness tmax and a minimum thickness tmin by using a flatness measuring device of an optical interferometer method. In the measurement of the maximum thickness tmax and the minimum thickness tmin, the second surface of the silicon substrate was fixed to a placement surface of the flatness measuring device, and the maximum thickness tmax and the minimum thickness tmin from the reference surface to the first surface were measured with the placement surface of the flatness measuring device set as the reference surface. The TTV [μm] has a value obtained by rounding off a second decimal place as a significant figure.

Both the maximum peak height Rp and the arithmetic average roughness Ra were measured with a white interferometer (white interferometer manufactured by Zygo Corporation: Nexview). For each specimen, the arithmetic average roughness Ra and the maximum peak height Rp were measured at any five observation positions in the first surface including the peripheral edge, and the average value of the obtained values was defined as the arithmetic average roughness Ra and the maximum peak height Rp of the specimen. It is noted that each observation position was set to a visual field range of a square of 1500 μm in length and 1500 am in width. The maximum peak height Rp [nm] and the arithmetic average roughness Ra [nm] have values obtained by rounding off a second decimal place as a significant figure.

TABLE 1

| | Slicing step | | | | | |
|---|---|---|---|---|---|---|
| | | | Plate member | | | |
| | | | | | Number of | Thickness |
| | Ingot | | Vertical | Horizontal | vertices | t2 |
| Specimens | Material | Crystal type | [mm] | [mm] | [pieces] | [mm] |
| Specimen 1 | Si | Columnar crystal | 300 | 300 | 4 | 1.0 |
| Specimen 2 | Si | Columnar crystal | 510 | 515 | 4 | 1.0 |
| Specimen 3 | Si | Columnar crystal | 600 | 600 | 4 | 1.0 |
| Specimen 4 | Si | Columnar crystal | 300 | 300 | 4 | 1.6 |
| Specimen 5 | Si | Columnar crystal | 510 | 515 | 4 | 1.6 |
| Specimen 6 | Si | Columnar crystal | 600 | 600 | 4 | 1.6 |
| Specimen 7 | Si | Columnar crystal | 900 | 900 | 4 | 1.0 |
| Specimen 8 | Si | Columnar crystal | 510 | 515 | 4 | 2.2 |
| Specimen 9 | Si | Columnar crystal | 300 | 300 | 4 | 1.0 |
| Specimen 10 | Si | Columnar crystal | 900 | 900 | 4 | 2.0 |
| Specimen 11 | Si | Columnar crystal | 600 | 600 | 4 | 1.0 |
| Specimen 12 | Si | Polycrystal | 510 | 515 | 4 | 2.2 |
| Specimen 13 | Si | Columnar crystal | 600 | 600 | 4 | 1.0 |
| Specimen 14 | Si | Columnar crystal | 600 | 600 | 4 | 1.0 |
| Specimen 15 | Si | Columnar crystal | 300 | 300 | 4 | 1.6 |
| Specimen 16 | Si | Columnar crystal | 510 | 515 | 4 | 1.6 |
| Specimen 17 | Si | Single crystal | 300 | 300 | 4 | 1.6 |
| Specimen 18 | Si | Columnar crystal | 900 | 900 | 4 | 3.3 |
| Specimen 19 | Si | Columnar crystal | 300 | 300 | 4 | 0.8 |
| Specimen 20 | Si | Columnar crystal | 600 | 600 | 4 | 2.2 |
| Specimen 21 | Si | Columnar crystal | 515 | 510 | 4 | 2.3 |
| Specimen 22 | Si | Columnar crystal | Diameter | — | 0 | 1.0 |
| | | | 450 | | | |
| Specimen 23 | Si | Columnar crystal | 300 | 300 | 4 | 1.2 |
| Specimen 24 | Si | Columnar crystal | 600 | 600 | 4 | 1.6 |
| Specimen 25 | Glass | Columnar crystal | 600 | 500 | 4 | 1.2 |

TABLE 2

| | | | | | Polishing step | | |
|---|---|---|---|---|---|---|---|
| | Grinding step | | | | | Hydrogen ion | |
| | | | Thickness | | Presence or | exponent of | Thickness |
| | | Material of | t3 of plate | Presence or | absence of | polishing | t4 of plate |
| | | abrasive | member after | absence of | polishing | solution for | member after |
| Specimens | Device | grains | step [mm] | etching step | step | finishing [pH] | step [mm] |
| Specimen 1 | Lapping machine | SiC | 0.9 | Not performed | Performed | 8.9 | 0.8 |
| Specimen 2 | Tapping machine | SiC | 0.9 | Not performed | Performed | 8.9 | 0.8 |
| Specimen 3 | Lapping machine | SiC | 0.9 | Not performed | Performed | 7.2 | 0.8 |
| Specimen 4 | Plane grinding | SiC | 1.5 | Not performed | Performed | 8.9 | 1.4 |
| | machine | | | | | | |
| Specimen 5 | Plane grinding | SiC | 1.5 | Not performed | Performed | 7.2 | 1.4 |
| | machine | | | | | | |
| Specimen 6 | Lapping machine | SiC | 1.5 | Not performed | Performed | 8.9 | 1.4 |
| Specimen 7 | Lapping machine | Al₂O₃ | 0.9 | Not performed | Performed | 7.2 | 0.8 |
| Specimen 8 | Plane grinding | Al₂O₃ | 2.1 | Not performed | Performed | 8.9 | 2.0 |
| | machinc | | | | | | |
| Specimen 9 | Lapping machine | SiC | 0.6 | Not performed | Performed | 7.2 | 0.5 |
| Specimen 10 | Plane grinding | Al₂O₃ | 1.8 | Not performed | Performed | 8.9 | 1.7 |
| | machine | | | | | | |
| Specimen 11 | Lapping machine | SiC | 0.9 | Not performed | Performed | 8.3 | 0.8 |
| Specimen 12 | Lapping machine | SiC | 1.5 | Not performed | Performed | 9.0 | 1.4 |
| Specimen 13 | Lapping machine | SiC | 0.9 | Not performed | Performed | 7.0 | 0.8 |
| Specimen 14 | Lapping machine | SiC | 0.9 | Not performed | Performed | 9.0 | 0.8 |
| Specimen 15 | Lapping machine | Al₂O₃ | 0.9 | Not performed | Performed | 8.9 | 0.8 |
| Specimen 16 | Lapping machine | SiC | 0.9 | Not performed | Performed | 7.2 | 0.8 |
| Specimen 17 | Lapping machine | Al₂O₃ | 0.9 | Not performed | Performed | 8.9 | 0.8 |
| Specimen 18 | Plane grinding | Al₂O₃ | 2.3 | Not performed | Performed | 8.3 | 2.2 |
| | machine | | | | | | |
| Specimen 19 | Lapping machine | SiC | 0.5 | Not performed | Performed | 8.3 | 0.4 |
| Specimen 20 | Plane grinding | Al₂O₃ | 1.9 | Not performed | Performed | 8.9 | 1.8 |
| | machine | | | | | | |
| Specimen 21 | Plane grinding | SiC | 0.9 | Not performed | Performed | 8.9 | 0.8 |
| | machine | | | | | | |
| Specimen 22 | Lapping machine | SiC | 0.9 | Not performed | Performed | 7.2 | 0.8 |
| Specimen 23 | Tapping machine | SiC | 0.8 | Not performed | Not | — | 0.8 |
| | | | | | performed | | |
| Specimen 24 | Lapping machine | SiC | 0.9 | Performed | Performed | 7.5 | 0.8 |
| Specimen 25 | Lapping machine | SiC | 0.9 | Not performed | Performed | 7.2 | 0.8 |

TABLE 3

| | | | TTV/area × | |
|---|---|---|---|---|
| Specimens | TTV [μm] | Rp [nm] | 10⁻⁶ [1/mm] | Ra [nm] |
| Specimen 1 | 9.8 | 23.4 | 0.11 | 0.6 |
| Specimen 2 | 13.2 | 33.2 | 0.05 | 0.7 |
| Specimen 3 | 17.9 | 45.6 | 0.05 | 0.7 |
| Specimen 4 | 4.0 | 11.5 | 0.04 | 0.5 |
| Specimen 5 | 8.4 | 31.2 | 0.03 | 0.7 |
| Specimen 6 | 17.6 | 42.3 | 0.05 | 0.8 |
| Specimen 7 | 89.1 | 78.9 | 0.11 | 1.1 |
| Specimen 8 | 34.6 | 65.2 | 0.13 | 1.6 |
| Specimen 9 | 9.4 | 22.4 | 0.10 | 0.4 |
| Specimen 10 | 98.5 | 34.9 | 0.12 | 2.1 |
| Specimen 11 | 45.7 | 99.7 | 0.13 | 1.5 |
| Specimen 12 | 90.0 | 95.4 | 0.34 | 1.8 |
| Specimen 13 | 8.8 | 23.3 | 0.02 | 0.3 |
| Specimen 14 | 78.9 | 67.2 | 0.22 | 1.3 |
| Specimen 15 | 98.0 | 66.6 | 1.09 | 1.7 |
| Specimen 16 | 89.8 | 89.0 | 0.34 | 2.1 |
| Specimen 17 | 7.8 | 12.6 | 0.09 | 0.2 |
| Specimen 18 | 56.6 | 43.4 | 0.07 | 0.9 |
| Specimen 19 | 34.6 | 75.4 | 0.38 | 1.4 |
| Specimen 20 | 106.7 | 89.0 | 0.30 | 1.6 |
| Specimen 21 | 76.3 | 104.3 | 0.29 | 2.3 |
| Specimen 22 | 5.5 | 9.9 | 0.01 | 0.3 |
| Specimen 23 | 65.5 | 234.0 | 0.73 | 88.8 |
| Specimen 24 | 114.1 | 56.6 | 0.32 | 1.5 |
| Specimen 25 | 99.4 | 89.3 | 0.33 | 1.9 |

### (Evaluation Method for Each Specimen)

In order to evaluate the outer shape, the thickness, the thickness variation, and the roughness of the first surface of each of the manufactured specimens, it was confirmed whether or not the entire first surface could be used for circuit formation, whether or not a fine wiring pattern having a width of 2 μm could be formed on the first surface, and whether or not the first surface could be transported by a material hand in a case where a film forming process or the like was performed on the first surface.

### (A) Criteria for Determining Whether or not the Entire First Surface is Used

A case where the following (a1) and (a2) were satisfied was regarded as a pass, and a case where at least one of (a1) or (a2) was not satisfied was regarded as a fail. In a case where the maximum peak height Rp was 50.0 nm or less among the pass results, the evaluation was regarded as “excellent”. It is noted that in addition, (a1) is a matter for determining whether or not the silicon substrate can be divided with a good yield, and (a2) is a matter for determining the efficiency of the entire use because the efficiency of the entire use is lowered when a portion where the maximum peak height Rp is large and the level difference is present.

(a1) The shape of the silicon substrate is a square shape.

(a2) The maximum peak height Rp of the peaks is 100.0 nm or less.

### (B) Criteria for Determining Whether or not a Fine Wiring Pattern Having a Width of 2 μm can be Formed on First Surface

A case where the following (b1) and (b2) were satisfied was regarded as a pass, and a case where at least one of (b1) or (b2) was not satisfied was regarded as a fail. In a case where the TTV was 50.0 μm or less and the maximum peak height Rp was 50.0 nm or less among the pass results, the evaluation was regarded as “excellent”. It is noted that in addition, (b1) is a matter for determining the thickness variation that may affect the circuit formation, and (b2) is a matter for determining the roughness of the first surface that may affect the circuit formation because it is difficult to form a fine wiring in a portion where the maximum peak height Rp is large and the level difference is large.

(b1) TTV is 100.0 pam or less.

(b2) The maximum peak height Rp of the peaks is 100.0 nm or less.

### (C) Criteria for Whether or not Transportation is Possible

A case where the following condition (c1) was satisfied was regarded as a pass, and a case where the condition (c1) was not satisfied was regarded as a fail. (c1) is a matter for determining whether or not, as a silicon substrate having a dimension of one side of 300 mm or more and 900 mm or less, the silicon substrate can maintain its form when the silicon substrate is transported up, down, left, and right by a robot arm (material hand) in association with circuit formation, or whether or not the silicon substrate has a weight that allows the silicon substrate to be transported.

$$0.5 mm \leq thickness t 4 \leq 2. mm . \qquad ( c1 )$$

Table 4 shows use of the entire first surface, formation of the fine pattern, and transportability. In Table 4, with regard to the pass or the fail of the use of the entire first surface and the formation of the fine pattern, pass is represented by “B”, “excellent” is represented by “A”, and fail is represented by “C”. In addition, the transportability is represented by “A” for pass and “B” for fail.

TABLE 4

| | (A) | (B) | (C) |
|---|---|---|---|
| | Division of | Formation of fine | Transportation |
| Specimens | first surface | pattern on first surface | of plate member |
| Specimen 1 | A | A | A |
| Specimen 2 | A | A | A |
| Specimen 3 | A | A | A |
| Specimen 4 | A | A | A |
| Specimen 5 | A | A | A |
| Specimen 6 | A | A | A |
| Specimen 7 | B | B | A |
| Specimen 8 | B | B | A |
| Specimen 9 | A | A | A |
| Specimen 10 | A | B | A |
| Specimen 11 | B | B | A |
| Specimen 12 | B | B | A |
| Specimen 13 | A | A | A |
| Specimen 14 | B | B | A |
| Specimen 15 | B | B | A |
| Specimen 16 | B | B | A |
| Specimen 17 | A | A | A |
| Specimen 18 | A | B | B |
| Specimen 19 | B | B | B |
| Specimen 20 | B | C | A |
| Specimen 21 | C | C | A |
| Specimen 22 | C | A | A |
| Specimen 23 | C | C | A |
| Specimen 24 | B | C | A |
| Specimen 25 | B | B | A |

### Evaluation

In Specimens 1 to 17, since the outer shape when viewed from the first surface side is square or rectangular, the entire first surface can be used for circuit formation without waste. In addition, since the TTV is 100.0 μm or less and the thickness variation of the silicon substrate is small, and the maximum peak height Rp of the first surface is 100.0 nm or less and the roughness is also small, a fine wiring pattern can be formed. Further, since the thickness t4 of the silicon substrate is 0.5 mm or more and 2.0 mm or less, the silicon substrate can maintain a plate form even during transportation. It is noted that in Specimens 1 to 11, 13, and 14 consisting of columnar crystal silicon, the TTV, the maximum peak height Rp, and the arithmetic average roughness Ra tend to have values higher than those of Specimen 17 consisting of single-crystal silicon, which is considered to be affected by the grain boundary.

In addition, it was also confirmed that Specimens 1 to 11, 13, and 14 consisting of columnar crystal silicon have a bending strength higher than that of Specimen 17 consisting of single-crystal silicon, and thus Specimens 1 to 11, 13, and 14 can be prevented from being cracked. In addition, the first surface could be finished to have the same or better flatness as the flatness of the glass substrate of the reference example. It is noted that among Specimens 1 to 17, in specimens in which the usability of the entire first surface was regarded as “excellent”, the value (TTV/S1) was 0.12×10⁻⁶ [mm⁻¹] or less, and the arithmetic average roughness Ra was 1.8 nm or less. In the specimens in which the formability of a fine pattern was regarded as “excellent”, the value (TTV/S1) was 0.11×10⁻⁶ [mm)] or less, and the arithmetic average roughness Ra was 0.6 nm or less. It is noted that in specimens in which the formability of a fine pattern was regarded as “excellent”, the usability of the entire first surface was also regarded as “excellent”, and in this case, the TTV was 17.9 μm or less and the maximum peak height Rp was 45.6 nm or less.

In Specimen 18, the silicon substrate is thick, and thus the weight is increased, and the transportation is difficult. Furthermore, in a case where a chip is packaged as an interposer, the entire chip becomes thick, which is not preferable.

In addition, in Specimen 19, since the silicon substrate is thin, warping occurs in the silicon substrate during transportation, which is not preferable.

In Specimen 20, the thickness variation of the silicon substrate (TTV) is large, and in Specimen 21, the maximum peak height Rp is as large as 104.3 nm and the first surface is rough, so that a fine wiring pattern cannot be formed.

In Specimen 22, since the silicon substrate is circular, the peripheral edge region cannot be utilized for circuit formation. In Specimen 23, the first surface is formed to be rough because the polishing step is not performed unlike the manufacturing method of the embodiment of the present invention, and thus the fine wiring pattern cannot be satisfactorily formed.

In Specimen 24, the TTV (thickness variation of the silicon substrate) is large, and thus a fine wiring pattern cannot be formed. It is considered that, by performing the etching step, a difference in the amount of etching occurs between the grain boundary portion and the other portions of the first surface, and thus the TTV is increased.

### INDUSTRIAL APPLICABILITY

According to the present invention, it is possible to provide a method for manufacturing a square silicon substrate.

### REFERENCE SIGNS LIST

1, 1A Square silicon substrate
11 First edge portion
12 Second edge portion
13 Corner portion
15 Cutout portion
110 First surface
120 Second surface
130 Outer peripheral end surface
200 Surface plate
210 Placement surface
tmax Maximum thickness
tmin Minimum thickness
S01 Slicing step
S02 Grinding step
S03 Polishing step

1. A square silicon substrate,
wherein a thickness is 0.5 mm or more and 2.0 mm or less,
a total thickness variation (hereinafter, referred to as TTV) in a first surface for circuit formation is 100.0 m or less, and
a maximum peak height Rp of the first surface is 100.0 nm or less.

2. The square silicon substrate according to claim 1,
wherein the square silicon substrate consists of polycrystalline silicon.

3. The square silicon substrate according to claim 1,
wherein a value (TTV/S1) obtained by dividing the TTV by an area (S1 [mm²]) of the first surface is 1.00×10⁻⁶ [mm⁻¹] or less.

4. The square silicon substrate according to claim 1,
wherein an arithmetic average roughness Ra of the first surface is 2.0 nm or less.

5. A method for manufacturing a square silicon substrate having a first surface for circuit formation and a second surface located opposite to the first surface, the method comprising:
a slicing step of slicing a silicon ingot to form a square plate member;
a grinding step of grinding both surfaces of the plate member; and
a polishing step of mechanically polishing one surface of the plate member subjected to the grinding step to form the first surface in the square silicon substrate,
wherein the square silicon substrate is formed to have a thickness of 0.5 mm or more and 2.0 mm or less without performing chemical etching in the grinding step, in the polishing step, and between the grinding step and the polishing step.

6. The method for manufacturing a square silicon substrate according to claim 5,
wherein, in the polishing step, slurry for finishing consisting of abrasive grains for finishing and a liquid having a hydrogen ion exponent of 7.0 or more and 9.0 or less is used.
